(19) United States
(12) Patent Application Publication
(10) Pub. No.: US 2008/0232155 A1
(43) Pub. Date: Sep. 25, 2008

(54) MOLECULAR BATTERY MEMORY DEVICE AND DATA PROCESSING SYSTEM USING THE SAME

(75) Inventor: Kazuhiko Kajigaya, Tokyo (JP)

Correspondence Address: Young & Thompson, Suite 500, 209 Madison Street, Alexandria, VA, 22314, US

(73) Assignee: Elpida Memory, Inc., Tokyo (JP)

(21) Appl. No.: 12/051,022

(22) Filed: Mar. 19, 2008

(30) Foreign Application Priority Data
Mar. 23, 2007 (JP) 2007-077578

(51) Int. Cl. G11C 11/00

(52) U.S. Cl. 365/151; 365/153

(57) ABSTRACT

Each memory cell of a molecular battery memory device includes a combination of a molecular battery and a selection transistor, and a parasitic capacitance is present in the molecular battery. A PN junction is present in the selection transistor, and is inversely biased. Therefore, a junction leak current flows. Accordingly, a charge accumulated in the parasitic capacitance is gradually discharged by a junction leak of the selection transistor, and a final potential of a node decreases toward a substrate potential Vs of the transistor. However, a difference between a substrate potential Vs and a reference potential Vp (=Vs−Vp) is set substantially equal to an open-circuit voltage of the molecular battery. Because the potential of the node converges to the open-circuit voltage without exception from the viewpoint of a plate wiring, an S/N ratio at the data reading time can be increased.

### TECHNICAL FIELD

The present invention relates to a memory device using an electrochemically chargeable and dischargeable molecular battery as a memory element. The present invention also relates to a data processing system that includes the memory device using the molecular battery.

### BACKGROUND OF THE INVENTION

Various kinds of hierarchically structured memory devices are used for a personal computer, a server or the like. A lower-layer memory device is required to be manufactured at low cost and have a large capacity, and an upper-layer memory device is required to perform a high-speed access. A magnetic storage such as a hard disk drive and a magnetic tape is generally used for a lowest-layer memory device. The magnetic storage is nonvolatile, and can store an extremely large amount of data at low cost as compared with a semiconductor memory. However, the magnetic storage has a slow access speed, and has no random accessibility in many cases. Therefore, programs and data to be stored in a long term are stored in the magnetic storage, and the stored programs and data are transferred to the upper-layer memory device according to need.

A main memory is an upper-layer memory device than the magnetic storage. In general, a DRAM (Dynamic Random Access Memory) is used for the main memory. The DRAM can perform higher-speed access than the magnetic storage, and has random accessibility. The DRAM also has a characteristic that an unit cost per bit is lower than that of a high-speed semiconductor memory such as an SRAM (Static Random Access Memory).

The uppermost-layer memory device is a built-in cache memory incorporated in an MPU (Micro Processing Unit). The built-in cache memory is connected to a core of the MPU via an internal bus, and therefore, has an extremely high-speed access. However, a securable memory capacity is extremely small. As a memory device constituting a hierarchy between the built-in cache and the main memory, a secondary cache or a tertiary cache is often used.

The DRAM is selected as the main memory because the DRAM has an excellent balance between the access speed and a bit unit cost. Among semiconductor memories, there are developed chips having a large capacity, and a capacity exceeding one gigabit in recent years. However, when the memory capacity of the DRAM is increased, area occupied per one cell capacitor becomes small, and capacitance decreases by this amount. To solve this problem, it is necessary to further progress the increasing of three dimensions of the cell capacitor. However, when the three dimensions of the cell capacitor are excessively increased, this complicates the process and increases manufacturing cost.

Meanwhile, as a semiconductor memory replacing DRAMs, a new type of memory using oxidation reduction reaction of molecules has been proposed (see Japanese Patent Application National Publication No. 2003-520384, U.S. Pat. No. 6,921,475, ZettaCore Molecular Technology (Stanford Computer Systems Colloquium, Apr. 20, 2005), and Tapping ZettaRAM™ for Low-Power Memory Systems (Processings of the 11th Int'l Symposium on High-Performance Computer Architecture (HPCA-11 2005))). This type of memory is called a “molecular battery memory”, which stores data using charge and discharge operations following electrochemical reaction of a molecular battery constituting a memory element. According to the molecular battery memory, a charge accumulation amount per unit area is larger than that of the DRAM using a normal capacitor. Therefore, it is expected to be able to obtain a sufficient S/N ratio without excessively increasing the three dimensions of the capacitor.

A molecular battery memory cell includes a combination of one molecular battery and one selection transistor, and has a structure similar to that of a DRAM cell. However, the molecular battery has an electrode structure of parallel flat plates, and has a parasitic capacitance separately from the element of the intrinsic molecular battery. Therefore, the molecular battery has a problem in that a charge and discharge current of the parasitic capacitance becomes noise. That is, during a data reading time, the charge and discharge current due to the parasitic capacitance flows separately from an oxidation reduction current following the electrochemical reaction. The charge and discharge current becomes noise to the oxidation reduction current, and this degrades the S/N ratio.

In the molecular battery memory cell, a MOSFET can be used as a selection transistor like in the DRAM cell. However, an inversely biased PN junction is present between a storage electrode of the molecular battery and a transistor substrate, and a junction leak current flows as a result. Due to the junction leak, a voltage between a cathode and an anode during a standby (pre-charge) period converges to a certain voltage determined by an open-circuit voltage Voc, a leak destination potential (substrate potential), and a leak current of the junction, and there is a problem in that the voltage easily becomes unstable. Particularly, because a leak current varies in each cell, a finally determined voltage is different in each cell. Therefore, the S/N ratio is further degraded.

### SUMMARY OF THE INVENTION

It is therefore an object of the present invention to provide a molecular battery memory device of which S/N ratio during a reading time is improved.

The above and other object of the present invention can be accomplished by a molecular battery memory device comprising a molecular battery that is electrochemically chargeable and dischargeable and having first and second ends between which a predetermined open-circuit voltage appears in a steady state, and a selection transistor including a first diffusion layer and a second diffusion layer biased oppositely to the first diffusion layer, wherein the first end of the molecular battery is connected to a plate wiring, the second end of the molecular battery is connected to the first diffusion layer, and a voltage between the plate wiring and the second diffusion layer is set equally to the open-circuit voltage.

According to the present invention, even when a junction leak current flows from the first diffusion layer to the second diffusion layer, voltages at both sides of the molecular battery converge to an open-circuit voltage or its vicinity without exception. Therefore, the S/N ratio during a data reading time can be increased.

The above and other object of the present invention can also be accomplished by a molecular battery memory device comprising a molecular battery that is electrochemically chargeable and dischargeable and having a predetermined open-circuit voltage in a steady state, and a selection transistor that is brought into a conductive state in response to an activation of a word line, wherein the molecular battery and the selection transistor are connected in series between a bit line and a plate wiring, and a voltage between the plate wiring and the bit wiring is set substantially equal to the open-circuit voltage so as to read data from the molecular battery.

According to the present invention, even when the selection transistor is turned on, a charge and discharge current due to the parasitic capacitance does not flow. When the molecular battery is in one of the reduction state and the oxidized state, the potential of the bit line does not change, and the potential of the bit line changes in the other state. Therefore, a high S/N ratio can be obtained.

Further, the above and other object of the present invention can also be accomplished by a data processing system comprising a data processor and a molecular battery memory device, wherein the molecular battery memory device includes a molecular battery that is electrochemically chargeable and dischargeable and having first and second ends between which a predetermined open-circuit voltage appears in a steady state, and a selection transistor including a first diffusion layer and a second diffusion layer biased oppositely to the first diffusion layer, and the first end of the molecular battery is connected to a plate wiring, and the second end of the molecular battery is connected to the first diffusion layer, and a voltage between the plate wiring and the second diffusion layer is set equally to the open-circuit voltage.

As explained above, according to the present invention, the S/N ratio at the time of actually reading data from the molecular battery can be improved. Therefore, a molecular battery memory device capable of performing a high-speed and reliable read operation can be provided.

### BRIEF DESCRIPTION OF THE DRAWINGS

The above and other objects, features and advantages of this invention will become more apparent by reference to the following detailed description of the invention taken in conjunction with the accompanying drawings, wherein:

FIG. 1 is a schematic diagram showing a configuration of a molecular battery memory device according to an exemplary embodiment of the present invention;

FIG. 2 is a basic circuit diagram showing a configuration of the memory cell MC;

FIG. 3A is a schematic diagram showing a basic structure of the molecular battery 11;

FIG. 3B is an equivalent circuit of the molecular battery 11 shown in FIG. 3A;

FIG. 4 is a graph showing an electric characteristic of the intrinsic molecular battery 25;

FIG. 5 is a schematic cross-sectional view showing a structure of the selection transistor 12;

FIG. 6 is an equivalent circuit diagram of the memory cell MC shown in FIG. 2;

FIG. 7 is an equivalent circuit diagram of the memory cell MC in a state that the substrate potential Vs is set to 0 V (ground potential) and the reference potential Vp is set to −0.3 V;

FIG. 8 is a timing diagram for explaining the operation at the time of writing “0” into the memory cell MC;

FIG. 9 is a timing diagram for explaining the operation at the time writing “1” into the memory cell MC;

FIG. 10 is a timing diagram for explaining the read operation to the memory cell MC;

FIG. 11 is a timing diagram for explaining the read operation to the memory cell MC;

FIG. 12 is a circuit diagram of the reference potential supply circuit 4; and

FIG. 13 is a block diagram showing a configuration of a data processing system 100 using a molecular battery memory device according to the preferred embodiment of present invention.

### DESCRIPTION OF THE PREFERRED EMBODIMENTS

Preferred embodiments of the present invention will now be described in detail hereinafter with reference to the accompanying drawings.

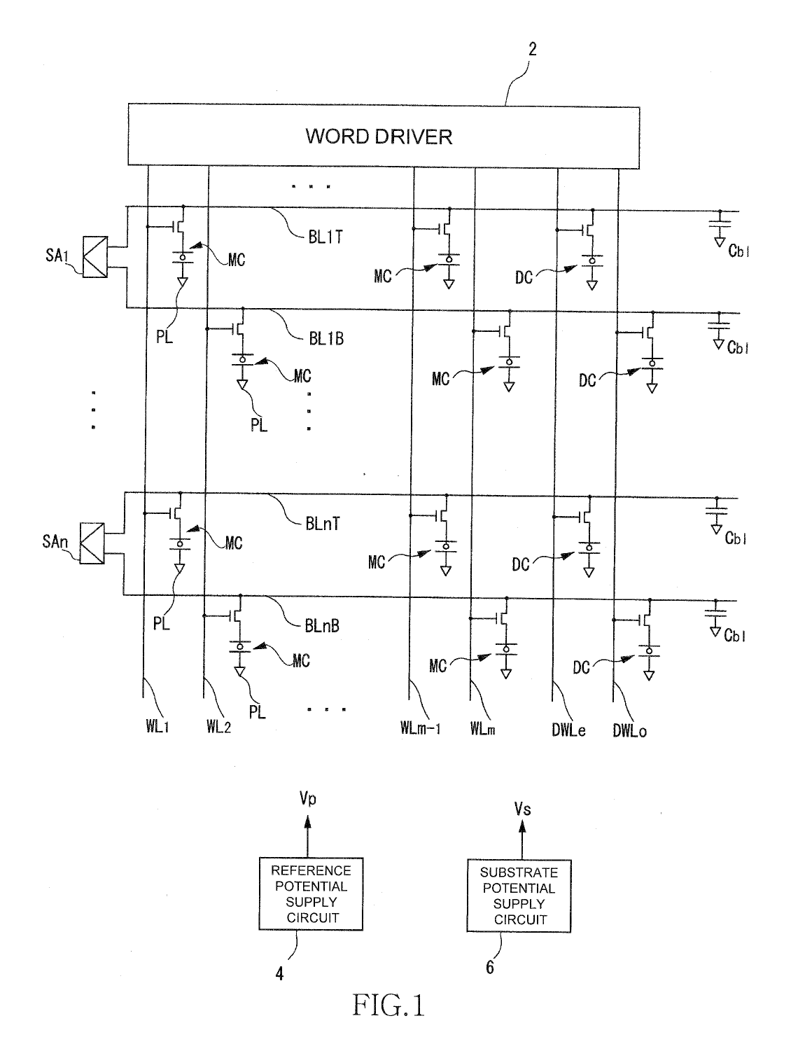

FIG. 1 is a schematic diagram showing a configuration of a molecular battery memory device according to an exemplary embodiment of the present invention.

As shown in FIG. 1, the molecular battery memory device according to the present embodiment has a configuration similar to that of a DRAM. Specifically, the molecular battery memory device includes plural word lines WL1 to WLm (expressed as “WL” where a distinction is not particularly necessary), plural bit line pairs BL1 to BLn (expressed as “BL” where a distinction is not particularly necessary), and plural memory cells MCs laid out at intersections between the word lines WLs and the bit lines BLs. Each memory cell MC includes a molecular battery and a selection transistor connected in series between a bit line BL and a corresponding plate wiring PL. Details of the memory cell MC are described later.

The molecular battery memory device according to the present embodiment further includes two dummy word lines DWLe, DWLo (expressed as “DWL” where a distinction is not particularly necessary). As shown in FIG. 1, each dummy cell DC is laid out at the intersection between the dummy word line DWL and the bit line.

The word lines WLs and the dummy word lines DWLs are connected to a word driver 2. The word driver 2 activates one of the word lines WL1 to WLm based on a row address supplied from the outside. When an even word line WL2i (i is an integer from 1 to m/2) is selected, the dummy word line DWLe is activated, and when an odd word line WL2i−1 is selected, the dummy word line DWLo is activated.

The bit line pairs BL are connected to corresponding sense amplifiers SA1 to SAn (expressed as “SA” where a distinction is not particularly necessary). The sense amplifier SA amplifies a fine signal at the time of reading data, and also drives a bit line at a predetermined potential at the time of writing data. That is, the sense amplifier SA serves as a bit line driver.

The bit line pairs BLs include bit lines BLjT and BLjB (j is an integer of 1 to n), respectively. The memory cells MCs are laid out at an intersection between the bit line BLjT and the odd word line WL2i−1, and at an intersection between the bit line BLjB and the even word line WL2i. The dummy cells DCs are laid out at an intersection between the bit line BLjT and the dummy word line DWLe, and at an intersection between the bit line BLjB and the dummy word line DWLo.

The molecular battery memory device according to the present embodiment further includes a reference potential supply circuit 4, and a substrate potential supply circuit 6. The reference potential supply circuit 4 is a circuit that supplies a reference potential Vp to a plate wiring PL. The substrate potential supply circuit 6 is a circuit that supplies a substrate potential Vs to a substrate (base) of a selection transistor.

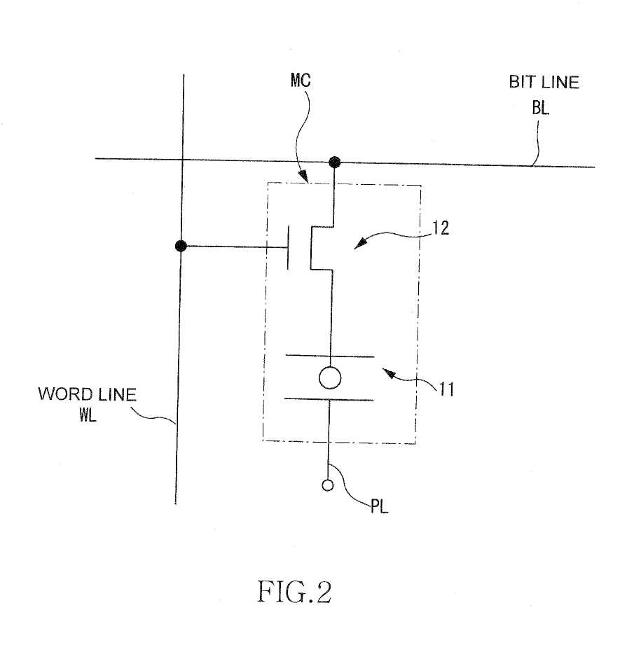

FIG. 2 is a basic circuit diagram showing a configuration of the memory cell MC.

As shown in FIG. 2, the memory cell MC includes a molecular battery 11 accumulating a charge using oxidation reduction reaction of molecules, and a selection transistor 12 for charging and discharging the molecular battery 11. An N-channel type MOS transistor (MOSFET) is preferably used for the selection transistor 12. A gate electrode of the selection transistor 12 is connected to the word line WL. Any one of a source electrode and a drain electrode is connected to the bit line BL, and the other of the source electrode and the drain electrode is connected to the anode electrode of the molecular battery 11. A cathode electrode of the molecular battery 11 is connected to the plate wiring PL. As described above, Vp is supplied to the plate wiring PL.

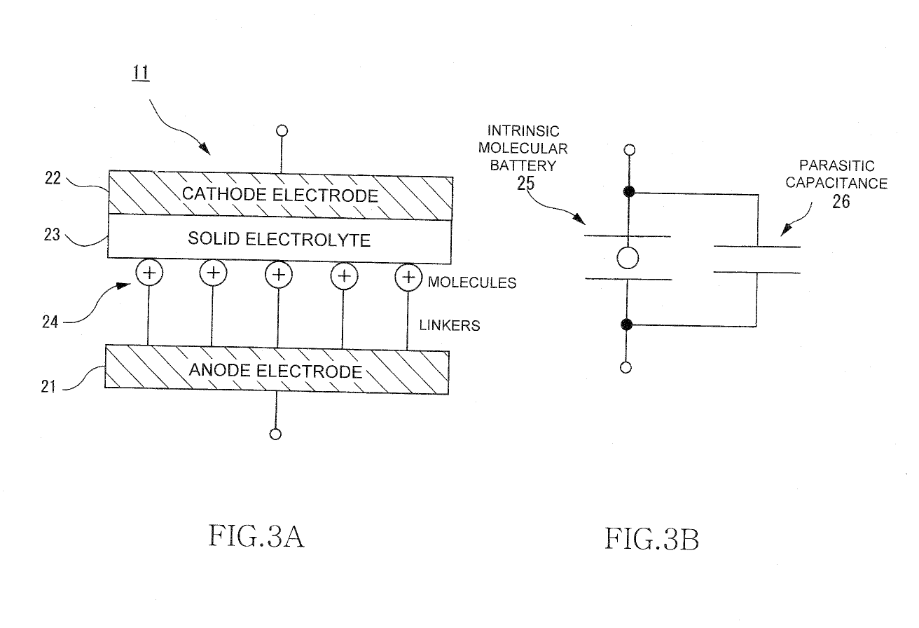

FIGS. 3A and 3B show a basic structure of the molecular battery 11, where FIG. 3A is a schematic diagram, and FIG. 3B shows an equivalent circuit thereof.

As shown in FIG. 3A, the molecular battery 11 includes an anode electrode 21, a cathode electrode 22, a solid electrolyte 23, molecules, and linkers 24. The anode electrode 21 and the cathode electrode 22 form an electrode structure of parallel flat plates. The solid electrolyte 23, the molecules, and the linkers 24 are present between the parallel flat plates. On the other hand, the equivalent circuit of the molecular battery 11 is expressed as shown in FIG. 3B, and has a structure that a parasitic capacitance 26 is connected in parallel to the intrinsic molecular battery 25.

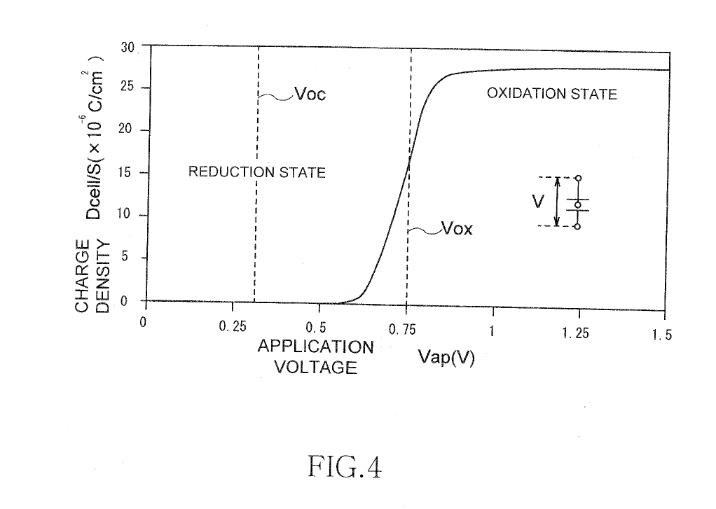

FIG. 4 is a graph showing an electric characteristic of the intrinsic molecular battery 25. A lateral axis expresses an application voltage Vap (V) applied from the outside to between the terminals, and a vertical axis expresses a charge density Q (×10⁻⁶ C/cm²) within the molecular battery.

As shown in FIG. 4, the charge density Q within the intrinsic molecular battery 25 rapidly changes with an oxidation potential Vox as a boundary. That is, when the application voltage Vap lower than the oxidation potential Vox is applied to between the terminals (Vap<Vox), electrons are taken into the intrinsic molecular battery 25, and the intrinsic molecular battery 25 becomes in the reduction state. The intrinsic molecular battery 25 becoming in the reduction state maintains this state so long as the application voltage Vap equal to or higher than the oxidation potential Vox is not applied to between the terminals. On the other hand, when the application voltage Vap equal to or higher than the oxidation potential Vox (Vap≧Vox) is applied to between the terminals, electrons are discharged from the intrinsic molecular battery 25, and the intrinsic molecular battery 25 becomes in the oxidation state. The intrinsic molecular battery 25 becoming in the oxidation state maintains this state so long as the application voltage lower than the oxidation potential Vox is not applied to between the terminals.

When the voltage application to the intrinsic molecular battery 25 is stopped, that is, when one of or both the anode electrode 21 and the cathode electrode 22 are set to the open state, the voltage between the terminals is held at the open-circuit voltage Voc. The open-circuit voltage Voc is substantially constant regardless of whether the intrinsic molecular battery 25 is in the reduction state or the oxidation state. Therefore, in the steady state that the selection transistor 12 is off, both ends of the intrinsic molecular battery 25 are always maintained at the open-circuit voltage Voc.

In the example shown in FIG. 4, the open-circuit voltage Voc is about 0.3 V, and the oxidation potential Vox is about 0.75 V. These voltages depend on materials constituting the intrinsic molecular battery 25. Therefore, in the present invention, values of the open-circuit voltage Voc and the oxidation potential Vox are not limited to these values. A size relationship between the open-circuit voltage Voc and the oxidation potential Vox also depends on materials constituting the intrinsic molecular battery 25. Therefore, depending on materials, the open-circuit voltage Voc can be equal to or higher than the oxidation potential Vox.

The reduction state and the oxidation state of the intrinsic molecular battery 25 are related to respective predetermined logic levels. For example, when the reduction state is “0” and when the oxidation state is “1”, one-bit data can be recorded into one intrinsic molecular battery 25.

While the dummy cell DC also has basically the same structure as that of the memory cell MC, the capacity of the intrinsic molecular battery 25 contained in the dummy cell DC is set to a smaller value than the capacity of the intrinsic molecular battery contained in the memory cell MC. This is because at the data reading time, a reference potential to perform the sense operation at the data reading time is necessary. Particularly, the capacity of the intrinsic molecular battery 25 contained in the dummy cell DC is set to preferably a half of the capacity of the intrinsic molecular battery contained in the memory cell MC. According to this, a potential difference necessary for the sense operation can be maximized.

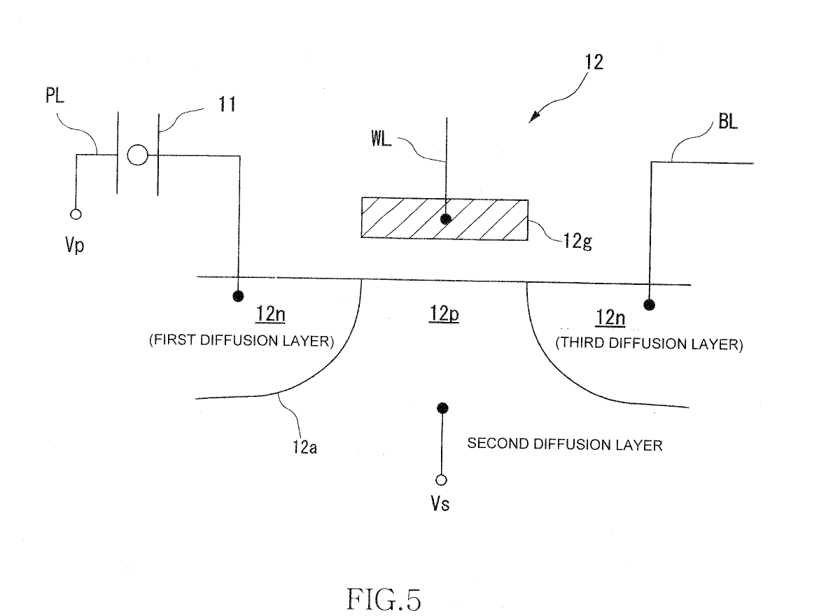

FIG. 5 is a schematic cross-sectional view showing a structure of the selection transistor 12.

As shown in FIG. 5, in the present embodiment, the selection transistor 12 includes an N-channel type MOS transistor (MOSFET). Therefore, the selection transistor 12 includes two n-type diffusion layers 12n becoming a source electrode and a drain electrode, a p-type diffusion layer 12p becoming a base, and a gate electrode 12g.

A connection part (PN junction 12a) between the n-type diffusion layers 12n and the p-type diffusion layer 12p is inversely biased. One of the n-type diffusion layers 12n is connected to the molecular battery 11, and the other n-type diffusion layer 12n is connected to the bit line BL. The gate electrode 12g is connected to the word line WL, and the two n-type diffusion layers 12n become in the conductive state in response to the activation of the word line WL.

The substrate potential Vs generated by the substrate potential supply circuit 6 shown in FIG. 1 is applied to the p-type diffusion layer 12p becoming the base of the MOSFET.

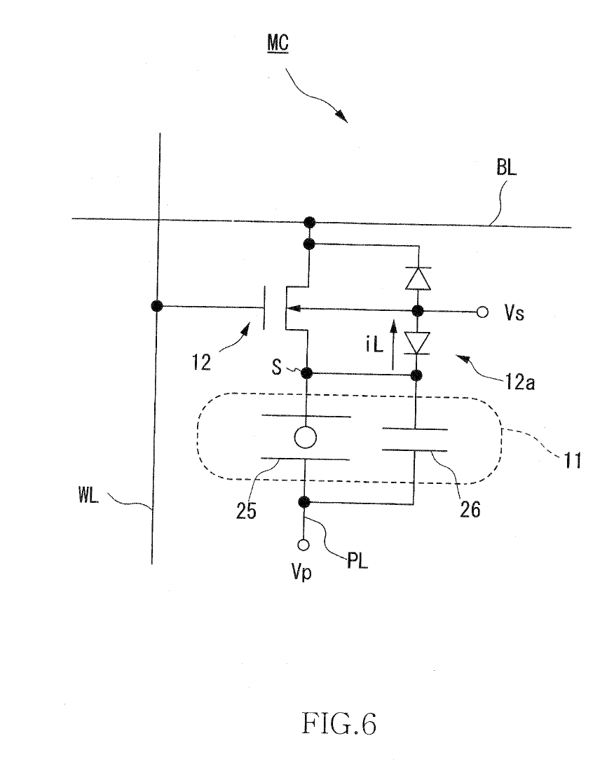

FIG. 6 is an equivalent circuit diagram of the memory cell MC shown in FIG. 2.

As shown in FIG. 6, the memory cell MC includes a combination of the molecular battery 11 and the selection transistor 12, and the parasitic capacitance 26 is present in the molecular battery 11. As shown in FIG. 5, because the PN junction 12a is present in the selection transistor 12 and is inversely biased, a junction leak current i_{L} flows. Therefore, a charge accumulated in the parasitic capacitance 26 is gradually discharged by the junction leak of the selection transistor 12, and a final potential of a node S decreases toward the substrate potential Vs of the transistor.

On the other hand, in the steady state that the selection transistor 12 is off, voltages at both ends of the intrinsic molecular battery 25 are going to converge to the open-circuit voltage Voc.

That is, both the work of converging to the substrate potential Vs by the junction leak and the work of converging to a sum of the potential of the plate wiring PL and the open-circuit voltage Voc (=Vp+Voc) operate in the node S. Therefore, when these two converged values are different, the potential of the node S varies depending on various conditions. This variation of the potential becomes a cause of lowering the S/N ratio at the data reading time.

Taking the above points into consideration, in the present invention, a voltage between the plate wiring PL and the substrate of the selection transistor 12, that is, a difference between the substrate potential Vs and the reference potential Vp (=Vs−Vp), is set substantially equal to the open-circuit voltage Voc of the molecular battery 11. That is, the difference is set to Vs−Vp=Voc. With this arrangement, the potential of the node S converges to the open-circuit voltage Voc without exception from the viewpoint of the plate wiring PL. Therefore, the S/N ratio at the data reading time can be increased.

In this case, it is preferable that one of the reference potential Vp and the substrate potential Vs is set to the ground potential. This is because the ground potential is a stable potential requiring no internal generation. It is particularly preferable that the substrate potential Vs is set as the ground potential. With this arrangement, the semiconductor substrate can be fixed to the ground potential.

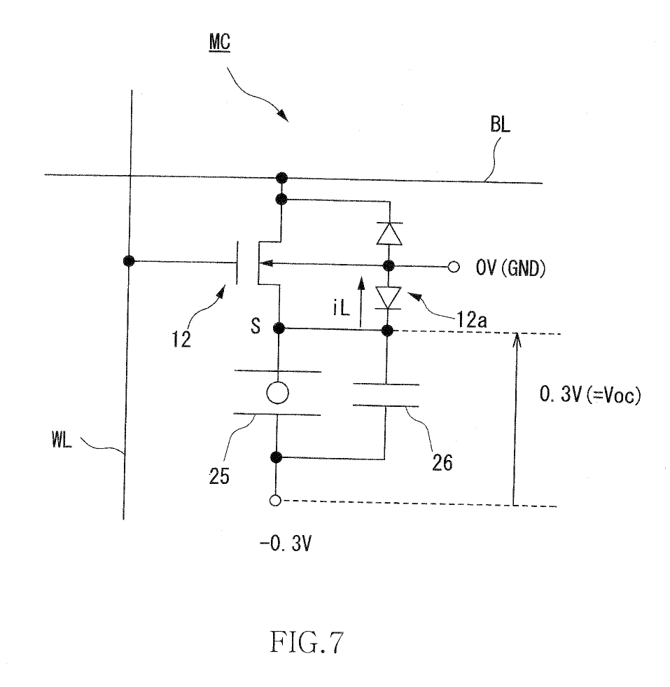

Therefore, when the open-circuit voltage Voc is set to 0.3 V, the substrate potential Vs can be set to 0 V, and the reference potential Vp can be set to −0.3 V, as shown in FIG. 7. With this arrangement, the potential of the node S always converges toward 0 V (ground potential). Accordingly, at the data reading time, a stable sense operation can be achieved without variation of the potential of the node S.

The operation of the molecular battery memory device according to the present embodiment is explained next. In the following explanations, it is assumed that the substrate potential Vs=0 V, the reference potential Vp=−0.3 V, the open-circuit voltage Voc=0.3 V, and the oxidation potential Vox=0.75 V.

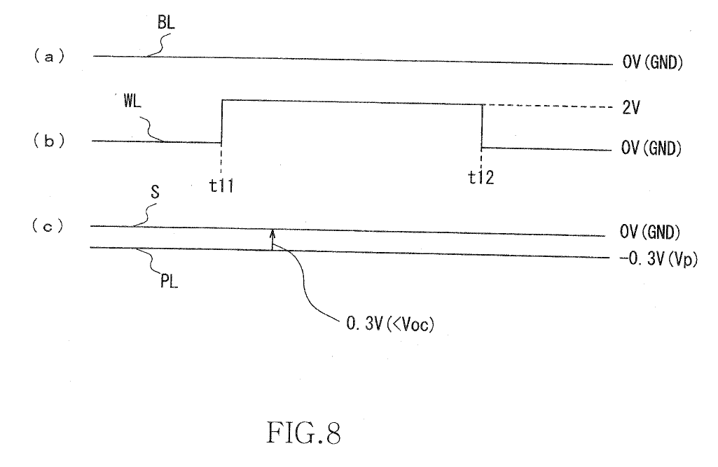

FIG. 8 is a timing diagram for explaining the operation at the time of writing “0” into the memory cell MC. In this case, the reduction state of the molecular battery 11 is defined as the logic value “0”.

As shown in FIG. 8, in writing “0” into the memory cell MC, a corresponding word line WL is activated during a period from time t11 to t12, and the potential of the bit line BL during this period is set to 0 V. In the present example, the word line WL is activated by changing the potential from 0 V to 2 V.

Because a relationship Vs-Vp=Voc is set in the present embodiment, the potential of the node S in the steady state converges to 0 V. Therefore, even when the selection transistor 12 is turned on during the period from time t11 to t12, the potential of the node S does not change, and a voltage of 0.3 V is applied to both ends of the molecular battery 11 (Vap=0.3 V). Because this voltage is lower than the oxidation potential. Vox (=0.75 V), the molecular battery 11 becomes in the reduction state. That is, the logic value “0” is written into the memory cell MC.

A potential of the bit line BL at the time of wiring “0” is not particularly limited when a difference between the potential of the bit line BL and the reference potential Vp is below the oxidation potential Vox. However, when the potential of the bit line BL at the time of writing “0” is coincided with the substrate potential Vs, the potential of the node S is immediately stabilized, because no current flows to the parasitic capacitance 26 after the selection transistor 12 is turned off.

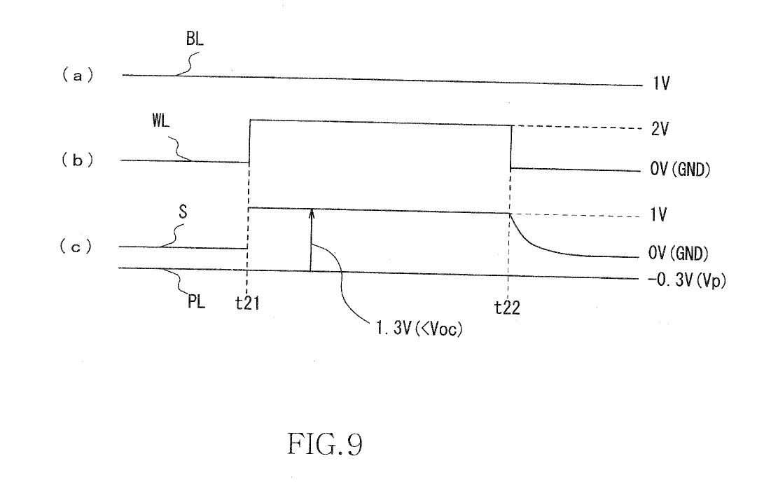

FIG. 9 is a timing diagram for explaining the operation at the time writing “1” into the memory cell MC. In this case, the oxidation state of the molecular battery 11 is defined as the logic value “1”.

As shown in FIG. 9, in writing “1” into the memory cell MC, a corresponding word line WL is activated during a period from time t21 to t22, and the potential of the bit line BL during this period is set to 1 V.

When the selection transistor 12 is turned on during the period from t21 to t22, the potential of the node S changes to 1 V. As a result, a voltage of 1.3 V is applied to both ends of the molecular battery 11 (Vap=1.3 V). Because this voltage is equal to or higher than the oxidation potential Vox (=0.75 V), the molecular battery 11 becomes in the oxidation state. That is, the logic value “1” is written into the memory cell MC.

After time t22 and in the state immediately after the selection transistor 12 is turned off, voltages at both ends of the molecular battery 11 are 1.3 V. However, the voltages at both ends of the molecular battery 11 gradually decrease based on the junction leak and the open-circuit characteristic of the molecular battery 11, and finally converge to the open-circuit voltage Voc. That is, the potential of the node S converges to 0 V.

A potential of the bit line BL at the time of wiring “1” is not particularly limited when a difference between the potential of the bit line BL and the reference potential Vp is equal to or higher the oxidation potential Vox.

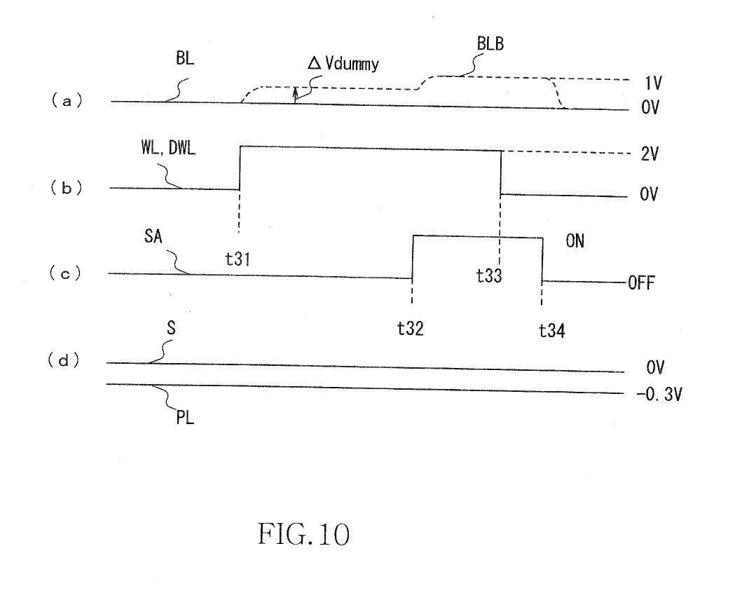

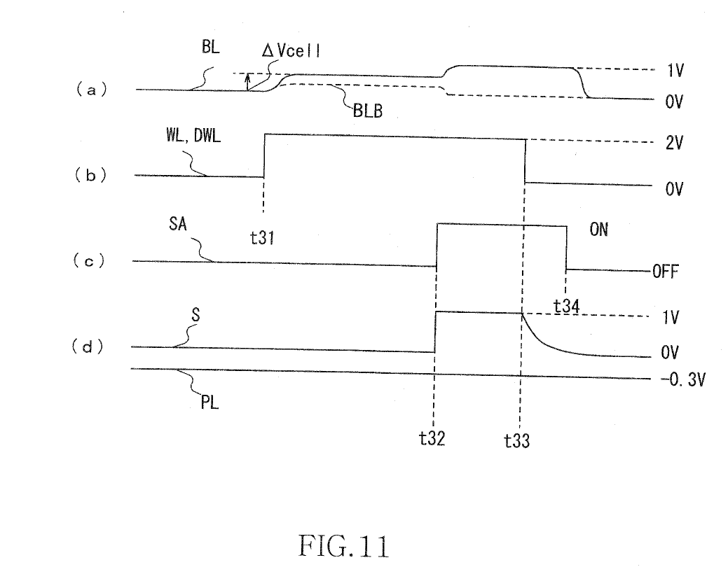

FIG. 10 and FIG. 11 are timing diagrams for explaining the read operation to the memory cell MC. FIG. 10 shows the case of reading “0” from the memory cell MC, and FIG. 11 shows the case of reading “1” from the memory cell MC.

In performing the read operation, the bit line pair BLT and BLB is first pre-charged to 0 V. That is, a voltage between the plate wiring PL and the bit line pair BLT and BLB is set to the same voltage as the open-circuit voltage Voc.

Next, when a corresponding word line WL and a dummy word line DWL are activated at time t31, a memory cell MC corresponding to the word line WL is connected to one bit line (BLT in this example), and a dummy cell DC corresponding to the dummy word line DWL is connected to the other bit line (BLB in this Example).

The molecular battery 11 contained in the dummy cell DC is always in the oxidation state. Therefore, when the molecular battery 11 is connected to the bit line BLB pre-charged to 0 V, the molecular battery 11 is deoxidized, and the potential of the bit line BLB slightly increases. When the accumulated charge of the molecular battery 11 contained in the dummy cell DC is Qdummy, a potential change amount ΔVdummy of the bit line BLB is expressed as ΔVdummy=Qdummy/C_{BL} (C_{BL} is a bit line capacitance).

On the other hand, the potential of the bit line BLT connected to the memory cell MC depends on a state of the molecular battery 11 contained in the memory cell MC. That is, as shown in FIG. 10, when the molecular battery 11 is in the reduction state, the potential of the bit line BLT does not change. Therefore, the potentials of the bit line pair become BLT<BLB.

Meanwhile, as shown in FIG. 11, the potential of the bit line BLT increases when the molecular battery 11 is in the oxidation state. When the accumulated charge of the molecular battery 11 contained in the memory cell MC is Qcell, a potential change amount ΔVcell of the bit line BLT is expressed as ΔVcell=Qcell/C_{BL}. As explained above, because the accumulated charge Qdummy of the dummy cell DC is smaller than (preferably a half of) the accumulated charge Qcell of the memory cell MC, the potentials of the bit line pairs become BLT>BLB in this case.

As explained above, after the potential difference occurs in the bit line pair, the sense amplifier SA is activated at time t32. Accordingly, the potential difference generated in the bit line pair is amplified, and data of “0” or “1” is read out. Data destroyed by the reading is also rewritten by activating the sense amplifier SA. Thereafter, at time t33, the word line WL and the dummy word line DWL are inactivated, and the sense amplifier SA is inactivated at time t34.

Immediately after “1” is read from the memory cell MC, voltages at both ends of the molecular battery 11 become 1.3 V by writing again. However, as described above, the voltages at both ends of the molecular battery 11 gradually decrease, and finally converge to the open-circuit voltage Voc.

As explained above, the molecular battery memory device according to the present embodiment makes the potential difference between the reference potential Vp and the substrate potential Vs coincide with the open-circuit voltage Voc. Therefore, the potential of the node S converges to the open-circuit voltage Voc without exception from the viewpoint of the plate wiring PL. Because the potential of the node S before the reading is stabilized, the S/N ratio at the data reading time can be increased.

In the present embodiment, a pre-charging is performed before the reading so that the voltage between the plate wiring PL and the bit line pair BLT and BLB coincides with the open-circuit voltage Voc. Therefore, when “0” is stored in the memory cell MC to be read, the bit line potential does not vary at all. Consequently, the sense operation can be performed easily.

In the present embodiment, the potential of the bit line BL at the time of writing “0” is coincided with the substrate potential Vs. Therefore, after the writing, no current flows to the parasitic capacitance 26. Consequently, the potential of the node S can be stabilized immediately.

Further, in the present embodiment, because the substrate potential Vs of the selection transistor 12 is set to the ground potential, the potential of the semiconductor substrate can be fixed to the ground potential. When the substrate potential Vs is set to the ground potential, the reference potential Vp can be generated in high precision. One example of the reference potential supply circuit 4 that generates the reference potential Vp is explained below.

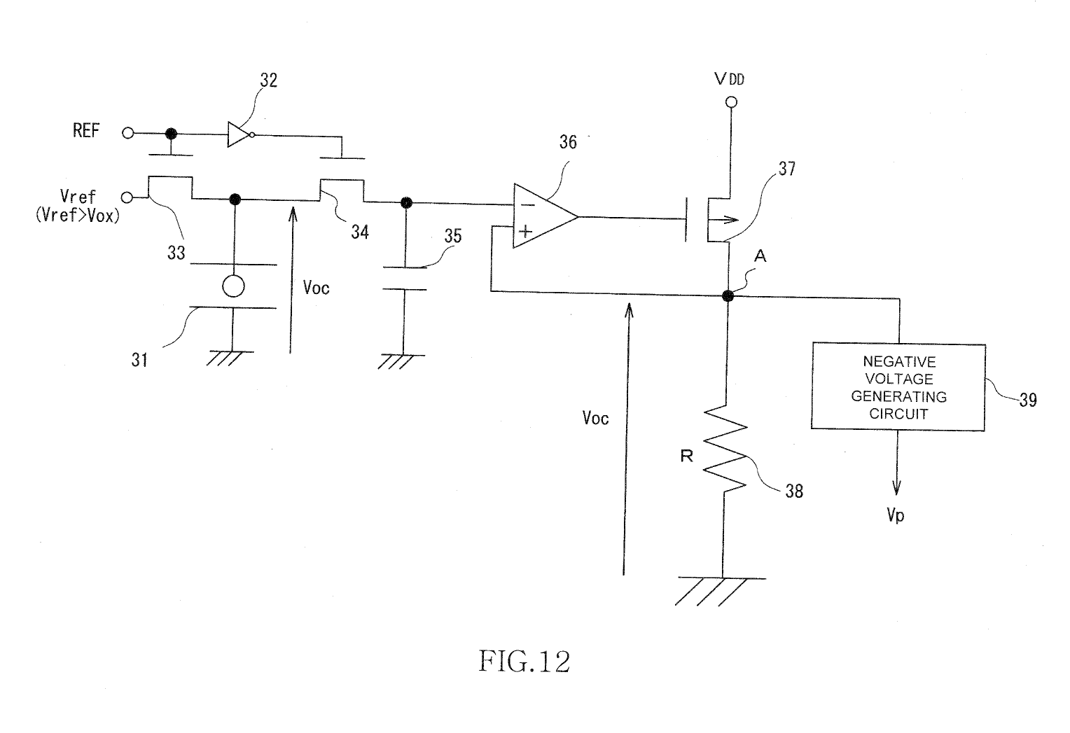

FIG. 12 is a circuit diagram of the reference potential supply circuit 4.

The reference potential supply circuit 4 shown in FIG. 12 has a monitoring molecular battery 31. The monitoring molecular battery 31 has the same structure as that of the molecular battery 11 used in the memory cell MC. Therefore, its open-circuit voltage Voc coincides with the open-circuit voltage Voc of the molecular battery used in the memory cell MC.

As shown in FIG. 12, one end of the monitoring molecular battery 31 is connected to the ground potential, and the other end is connected to transistors 33 and 34. The transistors 33 and 34 are controlled by a refresh signal REF, and a complementary signal is applied to their gates by an inverter 32 so that the transistors 33 and 34 are alternately turned on.

The refresh signal REF is at a low level in the steady state. Therefore, the open-circuit voltage Voc is supplied to an operation amplifier 36 via the transistor 34, and a voltage at a nodal point A between a transistor 37 and a resistor 38 is held at the open-circuit voltage Voc. The voltage at the nodal point A is supplied to a negative voltage generating circuit 39, thereby generating the reference potential Vp (−Voc).

The refresh signal REF periodically becomes at the high level, and the transistor 33 is turned on in response to this. When the transistor 33 is turned on, a predetermined voltage Vref is applied to the monitoring molecular battery 31, and the monitoring battery 31 is initialized. In this refresh operation, the open-circuit voltage Voc supplied to the operation amplifier 36 slightly varies. However, this variation is smoothed by a capacitor 35.

The present invention can preferably apply to a data processing system.

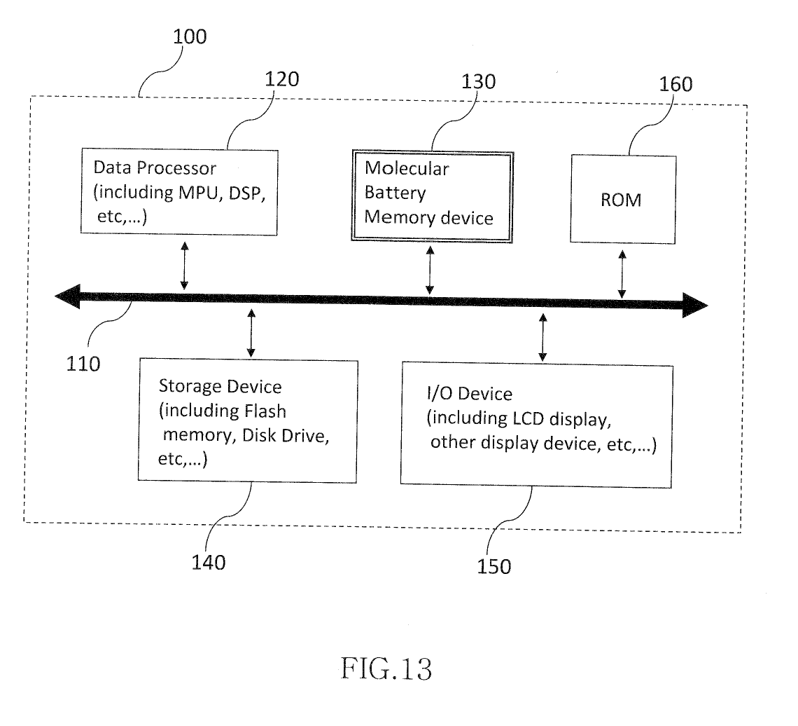

FIG. 13 is a block diagram showing a configuration of a data processing system 100 using a molecular battery memory device according to the preferred embodiment of present invention.

As shown in FIG. 13, the data processing system 100 includes a data processor 120 and a molecular battery memory device 130 according to the preferred embodiment connected to each other via a system bus 110. The data processor 120 can be selected from at least a microprocessor (MPU) and a digital signal processor (DSP). In FIG. 13, although the data processor 120 and the molecular battery memory device 130 are connected via the system bus 110 in order to simplify the diagram, they can be connected via not the system bus 110 but a local bus.

Further, in FIG. 13, although only one set of system bus 110 is employed in the data processing system 100 in order to simplify the diagram, a serial bus or a parallel bus connected to the system bus 110 via connectors can be provided. As shown in FIG. 13, a storage device 140, an I/O device 150, and a ROM 160 are connected to the system bus 110. However, they are not essential element for the data processing system 100.

The storage device 140 can be selected from at least a hard disk drive, an optical disk drive, and flash memory device. The I/O device 150 can be selected from a display device such as a liquid crystal display (LCD) and an input device such as a key board or a mouse. The I/O device 150 can consists of either input or output device. Further, although each one element is provided as shown in FIG. 13, two or more same elements can be provided in the data processing system.

The present invention has thus been shown and described with reference to specific embodiments. However, it should be noted that the present invention is in no way limited to the details of the described arrangements but changes and modifications may be made without departing from the scope of the appended claims.

For example, in the above embodiment, while the example that the open-circuit voltage Voc of the molecular battery 11 is below the oxidation potential Vex is explained, a relationship between the open-circuit voltage Voc and the oxidation potential Vox is optional. Therefore, the open-circuit voltage Voc can be equal to or higher than the oxidation potential Vox.

In the above embodiment, while the potential difference corresponding to the open-circuit voltage Voc is secured by setting the substrate potential to 0 V and setting the plate potential to −0.3 V, as an example, potentials and voltages are not limited to these values in the present invention. For example, various settings can be achieved, such as the substrate potential and the bit line pre-charge voltage can be set to 0.3 V, and the plate potential can be set to 0 V.

In the above embodiment, while the N-channel type MOS transistor is used for the selection transistor, the transistor is not limited to this in the present invention. Therefore, other switch elements, such as a bipolar transistor, can be used.

What is claimed is:

1. A molecular battery memory device comprising:
a molecular battery that is electrochemically chargeable and dischargeable and having first and second ends between which a predetermined open-circuit voltage appears in a steady state; and
a selection transistor including a first diffusion layer and a second diffusion layer biased oppositely to the first diffusion layer, wherein
the first end of the molecular battery is connected to a plate wiring,
the second end of the molecular battery is connected to the first diffusion layer, and
a voltage between the plate wiring and the second diffusion layer is set equally to the open-circuit voltage.

2. The molecular battery memory device as claimed in claim 1 further comprising a bit line and a word line, wherein the selection transistor further includes a third diffusion layer biased oppositely to the second diffusion layer, the bit line is connected to the third diffusion layer, and the first and the third diffusion layers become in a conductive state in response to an activation of the word line.

3. The molecular battery memory device as claimed in claim 2, wherein a voltage between the plate wiring and the bit line is set substantially equal to the open-circuit voltage so as to read data from the molecular battery.

4. The molecular battery memory device as claimed in claim 2, wherein a voltage between the plate wiring and the bit line is set below an oxidation potential of the molecular battery so as to write a first logic level into the molecular battery, and a voltage between the plate wiring and the bit line is set equal to or higher than the oxidation potential so as to write a second logic level into the molecular battery.

5. The molecular battery memory device as claimed in claim 1, wherein a potential of the second diffusion layer is set to a ground potential.

6. A molecular battery memory device comprising:
a molecular battery that is electrochemically chargeable and dischargeable and having a predetermined open-circuit voltage in a steady state; and
a selection transistor that is brought into a conductive state in response to an activation of a word line, wherein the molecular battery and the selection transistor are connected in series between a bit line and a plate wiring, and
a voltage between the plate wiring and the bit wiring is set substantially equal to the open-circuit voltage so as to read data from the molecular battery.

7. The molecular battery memory device as claimed in claim 6, wherein a voltage between the plate wiring and the bit line is set below an oxidation potential of the molecular battery so as to write a first logic level into the molecular battery, and a voltage between the plate wiring and the bit line is set equal to or higher than the oxidation potential so as to write a second logic level into the molecular battery.

8. The molecular battery memory device as claimed in claim 6, wherein a potential of the bit line is set to a ground potential so as to read data from the molecular battery.

9. The molecular battery memory device as claimed in claim 8, wherein a substrate potential of the selection transistor is set to the ground potential.

10. A molecular battery memory device comprising:
a bit line;
a plate wiring;
a memory cell including a molecular battery and a selection transistor connected in series between the bit line and the plate wiring;
a reference potential supply circuit providing a reference potential to the plate wiring;
a substrate potential supply circuit providing a substrate potential to the selection transistor; and
a bit line driver setting a potential of the bit line to a reading potential during reading data from the molecular battery, wherein
the molecular battery is electrochemically chargeable and dischargeable and has a predetermined open-circuit voltage in a steady state,
a difference between the reference potential and the substrate potential is substantially equal to the open-circuit voltage, and
a difference between the reference voltage and the reading potential is substantially equal to the open-circuit voltage.

11. The molecular battery memory device as claimed in claim 10, wherein
the bit line driver sets a potential of the bit line to a first or a second writing potential during writing data into the molecular battery,
a difference between the reference potential and the first writing potential is below an oxidation potential of the molecular battery, and
a difference between the reference potential and the second writing potential is equal to or higher than the oxidation potential of the molecular battery.

12. The molecular battery memory device as claimed in claim 11, wherein one of the first and the second writing potentials is equal to the reading potential.

13. The molecular battery memory device as claimed in claim 10, wherein the substrate potential is a ground potential.

14. The molecular battery memory device as claimed in claim 10 further comprising a dummy cell connected to between the bit line and the plate wiring, wherein a capacitance of a molecular battery contained in the dummy cell is smaller than a capacitance of the molecular battery contained in the memory cell.

15. A data processing system comprising a data processor and a molecular battery memory device, wherein the molecular battery memory device includes:
a molecular battery that is electrochemically chargeable and dischargeable and having first and second ends between which a predetermined open-circuit voltage appears in a steady state; and
a selection transistor including a first diffusion layer and a second diffusion layer biased oppositely to the first diffusion layer, and
the first end of the molecular battery is connected to a plate wiring, and the second end of the molecular battery is connected to the first diffusion layer, and
a voltage between the plate wiring and the second diffusion layer is set equally to the open-circuit voltage.
